(19) United States
(12) Patent Application Publication
(10) Pub. No.: US 2009/0309492 A1
(43) Pub. Date: Dec. 17, 2009

(54) Organic Light Emitting Component, and Production Method

(75) Inventors: Michael Hofmann, Dresden (DE); Martina Inhester, Bottrop (DE); Jan Birnstock, Dresden (DE); Thomas Luethge, Dortmund (DE); Dieter Adam, Soest (DE)

Correspondence Address: SUTHERLAND ASBILL & BRENNAN LLP, 999 PEACHTREE STREET, N.E., ATLANTA, GA, 30309, US

(73) Assignees: NOVALED AG, Dresden (DE); EVONIK DEGUSSA AG, Marl (DE)

(21) Appl. No.: 12/439,796

(22) PCT Filed: Sep. 3, 2007
(86) PCT No.: PCT/EP07/07673

§ 371 Date: Aug. 17, 2009

(30) Foreign Application Priority Data
Sep. 4, 2006 (EP) 06018493.4
Apr. 11, 2007 (EP) 07007413.3
Sep. 3, 2007 (WO) PCTEP2007007673

(51) Int. Cl. H01J 1/62; H01L 51/50

(52) U.S. Cl. 313/504; 438/22; 257/E21.001

(57) ABSTRACT

The invention relates to an organic light emitting component, particularly an organic light emitting diode, in which an arrangement is formed that comprises a bottom electrode, a top electrode, and an organic layer region which is located between and is in electrical contact with the bottom electrode and the top electrode and contains at least one hole transport layer, at least one electron transport layer, and a light-emitting area. The bottom electrode is formed from a dispersion as a structured, binder-free, and optically transparent bottom electrode layer made of a bottom electrode material by means of a wet chemical application process, said bottom electrode material being an optically transparent, electrically conductive oxide. The bottom electrode layer has a sheet resistance of less than about 500 Ω/square and an optical refractive index of less than 1.8.

The invention relates to an organic light-emitting component and a process for its production.

### BACKGROUND OF THE INVENTION

Organic light-emitting components such as light-emitting diodes (OLEDs) are used in very different applications as components that emit light during the placing of an electrical voltage. In certain applications there is the requirement of placing an efficient, long-lived, organic light-emitting component on a conductive, transparent base contact that is simple to structure, scatters as much light as possible and forms a base electrode of the component.

An important aspect is the simple and material-saving incorporation of the production of such a base electrode into a large-scale manufacturing process. Such production processes should furthermore customarily fulfill, in addition to the ensuring of preferred physical properties of the base contact, the following requirements: Optimal material yield, as few process steps as possible, variability in the layout and design of the component structures, variability of the substrate size and a simple scalability for large-area applications.

In known organic light-emitting components usually indium-tin oxide (ITO) is used as base electrode material for the base electrode. Here, ITO is deposited over a large area onto a substrate, for example, glass in the vacuum, e.g., by the sputtering technology. Thereafter, the desired base electrode structure is produced by exposing an applied, light-sensitive varnish to light and by its structuring using masks and after subsequent removal by etching of the non-required ITO's. A significant disadvantage of these standard lithography steps consists in that a part of the base electrode material applied over a large area in the vacuum is subsequently removed again during the etching so that it can no longer be used as base electrode material. Thus, material is wasted. A further disadvantage results from the complex structuring method. Each individual step requires expensive technical apparatuses and causes additional manufacturing costs.

Alternatively, the depositing of desired ITO conducting tracks can take place by shadow masks. Here, however, a so-called sub-sputtering occurs on account of scatter effects, which leads to fuzzy edges of the desired base electrode structure and as a consequence to imprecisely defined structure edges. Here too, the valuable base electrode material is utilized only in an insufficient manner since the predominant part is deposited on the shadow mask or on other surfaces inside the vacuum chamber.

If a change of the layout of the base electrode structure is required, new masks must be prepared in the previously described processes, which means that the structuring of the base electrode is always bound to the mask design. This is also associated with a limitation regarding the variability of the utilizable substrate size.

Further known processes for the separation of conductive oxides such as ITO that can be used to form optically transparent base electrodes in the form of an optically transparent base electrode layer are: PVD (“Physical Vapor Deposition”), CVD (“Chemical Vapor Deposition”), evaporation, spray pyrolysis, pulsed laser ablation and ion beam, deposition. Furthermore, processes were suggested that are based on a wet-chemical processing, for example, the sol-gel technology (cf. Aergeter et al., Journal of Sol-Gel Science and Technology 27, page 81, 2003). Here, an unstructured layer is produced in particular by spin-coating a liquid composition onto a substrate, which layer can be shaped in particular as an infrared-reflecting surface. Moreover, surfaces formed by stamping in the submicrometer range and consisting of conductive oxides have been realized.

In the known technologies for the production of a base electrode of ITO for an organic, light-emitting component the requirements and the parameters influencing the component function can frequently be fulfilled only insufficiently, which will be explained in detail in the following. To this end at first a few concepts will be defined in detail in the following.

Roughness designates in the sense of the present application the quadratic average roughness (RMS—“Root means square”) that indicates the average square deviation in height from the average height level in nanometers (nm). The scanning of the height structure takes place here, for example, with the raster power microscope on a measuring surface of 10 μm times 10 μm.

Surface resistance designates in the sense of the present application the ohmic resistance measured on a layer with a uniform layer thickness when a quadratic area of any desired size is contacted on two opposite edges and the current is detected as a function of the (direct) voltage. The surface resistance is measured in ohms (Ω) and indicated in Ω/square. The determination of the surface resistance can also take place according to other processes, for example, by four-point measuring.

Transmission capacity designates in the sense of the present application the transparence capacity of a body for light at a certain wavelength. The visible wavelength range is customarily a wavelength range of 380 nm to 750 nm. The transmission capacity of a coated glass can then be compared with the transmission capacity of the same uncoated glass by indication of percentage values.

Porosity designates in the sense of the present invention the property of a material to be provided with pores and to be permeable. It is indicated numerically in percentage, which defines the component of the pore volume in the total volume of the considered material.

The electrical conductivity of the base electrode scales in general with its layer density. However, as the layer density increases the absorption of the light increases that is produced in the organic range of the light-emitting component, and the transmission capacity decreases. Commercially available ITO conducting tracks deposited in the vacuum were optimized taking into consideration these two aspects for OLED applications. In the case of very good quality of an ITO layer with a thickness of 100 nm surface resistances up to 20 to 50 ohms/square can be achieved. The transmission capacity of such a base electrode is customarily 90% to 95% in the visible spectral range. Such base electrodes are customarily deposited at elevated temperatures (>200° C.) by magnetron sputtering technology.

Optically transparent base electrodes produced by sputtering processes and in accordance with the state of the art have very smooth surfaces of customarily less than 1 nm RMS. Data sheets from producers such as, for example, the ITO data sheet of Thin Film Devices Inc. furnish information about this. For applications of optically transparent electrodes in the display range (LCD, OLED, FED, plasma) a surface roughness of less than 1 nm of a 150 nm thick ITO layer is indicated there. Thus, for example, the ITO material is also used by the Applied Films firm with a surface resistance of 13 ohms/square and a measured RMS roughness of 0.8 nm (see Langmuir, 18, 2002, 450-457).

In spite of their low roughness, transparent base electrodes produced by sputtering processes frequently have local differences in height (“spikes”) of several nanometers (>10 nm), whose number rises especially with increasing layer thickness. The height of the local differences in height is in some instances on the order of the thickness of the organic layers from which the OLED is built up. In such instances the probability of short circuits, local current density peaks and elevated leakage currents rises, which customarily leads to a reduction of the efficiency and the service life of the organic light-emitting component. This effect can be reduced by a mechanical posttreatment of the deposited ITO base electrode in that an additional polishing step is provided. However, this is very time-consuming and expensive.

The problem of the surface properties is also discussed in the literature (Tak et al., Thin Solid Films, 411, 2002, 12-16): In order to be able to produce long-lived OLEDs, very smooth ITO surfaces are required. The surface roughness correlates with the stability of the OLEDs, It is also discussed (see J Vac Sc Tech A, 21 (4), 2003) that the surface roughness of the ITO is a critical factor in particular for OLED applications. The RMS value required by the industry is <1 nm. Accordingly, surfaces that are smooth as possible atomically should be produced in order to eliminate tracks for leakage currents. In this connection, electrodes with very smooth surfaces based on wet-chemical particulate ITOs have been realized whose layer smoothness has proven to be a particular advantage. The ITO layer used thus belongs to the state of the art.

According to the state of the art a posttreatment of ITO base contacts can be provided. It is especially necessary for an efficient production of light by the organic, light-emitting component that the positive and negative charge carriers are injected well into the charge carrier transport layers bordering on the two electrodes. Therefore, energetic barriers for the injecting of the charge carriers namely, of holes and electrons, should be as small as possible. It is necessary in customary organic, light-emitting diodes that do not have doped charge carrier transport layers that the ITO base electrode is suitably treated in order, for example, to significantly improve the injection of holes from the base electrode into the bordering charge carrier transport layer. This treatment is carried out, for example, with an oxygen- or UV-ozone plasma. Further suggestions for solutions use intermediate layers of polymerized, fluorinated carbon compounds or other organic hole injection layers. Thin charge carrier injection layers of molybdenum oxide or gold or the like are also used.

A significant improvement of the injection of charge carriers from the electrodes into the organic region of the light-emitting component is achieved with the aid of the electrical doping of charge carrier injection layers. Then, in particular no voltage losses occur at the boundary surfaces. The otherwise provided, additional ITO treatment for the improvement of the hole injection can then be eliminated.

### SUMMARY OF THE INVENTION

The invention has the task of creating an efficient and long-lived organic light-emitting component and a process for its production that support a material-saving and economical production, especially as regards the formation of a structured base electrode.

This task is solved in accordance with the invention by an organic light-emitting component in accordance with the independent Claim 1, a process for the production in accordance with the independent Claim 15 as well as by an article in accordance with the independent Claim 25. Advantageous embodiments of the invention result from the dependent subclaims.

An efficient decoupling of light in the organic, light-emitting component is ensured with the given refraction index, the high transparency and the utilization of scatter effects. The formation of the base electrode without binding agent favors porosity inside the base electrode layer. The material porosity results on the one hand in scatter effects and results on the other hand in a reduced refraction index of n>1.8 of the effective medium for the avoidance of waveguiding modes in the base electrode, so that the light produced in the visible range is decoupled better from the component. In addition, the porous base electrode formed without binding agent has a high transparency. In this manner the efficiency of the light emission of the organic, light-emitting component can be increased. The emission wavelength, that is slightly dependent on the observation angle, and that is normally expressed in a shift to shorter wavelengths, is also prevented by the porosity produced.

The effect of the waveguiding modes plays a part in such components if the layer thicknesses are on the order of the wavelength of the produced light and in addition surfaces of bordering layers have a significant refraction index difference, as is the case, for example, on the boundary between the organic range (typical refraction index n=1.7) and a customary ITO base electrode (n=2.2) or the boundary between such an ITO base electrode (n=2.2) and a glass substrate (n=1.5). Due to total reflection on the boundary surfaces to the ITO base electrode, it is possible in such an arrangement that a portion of the light modes is guided in the base electrode that is then not directly decoupled in the forward direction from the glass substrate but rather is absorbed or exits at the edges of the base electrode. This effect might be able to be avoided, for example, in that an ITO base electrode is provided with a low layer thickness, for example, with a layer thickness of approximately 20 nm. However, the electrical conductivity of such an ITO base electrode is too low. Since the formation of a base electrode with a refraction index of n<1.8 is provided, waveguiding modes are suppressed inside the base electrode layer.

A low feed resistance is additionally ensured in combination with the further features with the formation of a good conductive base electrode of transparent conductive oxide whose surface resistance is less than 500 Ω/square. Moreover, if high leakage currents are avoided that contribute to electrical losses inside the component, it becomes possible to produce efficient, long-lived light-emitting elements. It is therefore required that an inverse current is less than approximately 10⁻² mA/cm² in a current-voltage characteristic of the arrangement at a voltage of approximately −3 V applied on the arrangement.

The term long-lived OLEDs denotes in the sense of the present application organic, light-emitting diodes whose service lives exceed 1000 hours in typical application areas for certain brightnesses (approximately 500 cd/m²). The service life is defined as the time until the brightness has dropped to 50% of the initial value due to degradation processes.

It is provided that the base electrode is applied out of a dispersion. The concept dispersion designates in the sense of the present application a mixture of at least two substances that do not dissolve into each other or hardly dissolve into each other or unite chemically with each other. A substance is distributed as finely as possible here in another substance, namely, a so-called dispersing agent. The individual phases can be distinctly delimited from each other and as a rule separated from each other again by physical methods. A distinction is made between dispersions of the type of the aggregate state of the participating substances and of the particle size of the dispersed substance. If particles of a solid are dispersed in a liquid, one speaks of a suspension. So-called dispersing agents can be admixed, that bring about a better distribution of the substance in the dispersing agent in that, for example the wettability or an elevated electrostatic rejection of the particles to be dispersed is achieved.

The base electrode layer is produced without binding agent. The concept of binding agent is in the sense of the present invention a collective concept for products that connect the same or different substances with each other. Depending on the application, inorganic, organic, natural or synthetic binding agents are used. This setting takes place by means of physical drying, hardening or strong rise in viscosity, chemical reaction or hydration.

Optical elements are classified in the sense of the present invention as highly efficient if in particular the ohmic losses in the arrangement are minimized, for example, at a low electrical resistance of the electrodes and of the charge carrier transport layers and the most favorable optical conditions for the emission of light or decoupling of light are fulfilled.

A convenient embodiment of the invention provides that the base electrode material is formed from nanoparticles of electrically conductive materials. Nanoparticles are particles that have a diameter of 1 nm to 999 nm. Particle size distributions can be measured by dynamic light scatter, for example, with the apparatus type LB550 of the Horiba company nanoparticles are preferably dispersed until they have an average particle size that is at least smaller than the layer thickness to be applied. As regards the size distribution of the particles in the dispersion, no limitations are set. This means in particular that preferably no modal mixing ratios of certain particle sizes have to be produced, so that the production process of the nanoparticles to be used or a dispersion consisting of them is simplified.

An advantageous embodiment of the invention can provide that the base electrode material is a material from at least one material class selected from the following group of material classes: ternary material system such as In₂O₃:Sn (ITO), SnO₂:Sb (ATO), SnO₂:F, ZnO:Al, ZnO:In, Zn—Sn—O, Mg—In—O, Ga—In—O, Zn—In—O; quarternary material systems such as Zn—In—Sn—O (ZITO), Zn—In—Li—O, chemically modified, variant of the ternary material system, chemically modified variant of the quarternary material system, physically modified variants of the ternary material system, physically modified variants of the quarternary material system, and their mixtures.

A preferred further development of the invention can provide that the base electrode layer has a layer thickness between approximately 0.05 μm and approximately 20 μm, preferably between approximately 0.1 μm and approximately 2 μm. The use of a printed base electrode of ITO in particular results in the advantage that the dependency of the efficiency of the component on the layer thickness of the organic layer region almost disappears with increasing ITO layer thickness. This makes possible a large process window for the layer thicknesses of organic charge carrier transport layers. Likewise, a generalized structure that achieves qualitatively high characteristic data can be used in a simple manner for a so-called “unified RGB stack”, in which the identical layer construction with the same layer thicknesses is used for all three colors. This therefore results from a technical processing viewpoint in a simplified structuring and masking of the organic layers for multicolored RGB structures.

A further development of the invention can provide that the base electrode layer has an RMS roughness in the range of at least approximately 2 nm to at the most approximately 20 nm and preferably in a range of at the most approximately 10 nm. Examinations have shown that counter to the expectations, long-lived, highly efficient organic light-emitting elements were able to be produced. It was previously assumed in the state of the art that the base electrode must be especially smooth, thus, should be produced with <1 nm RMS.

An advantageous embodiment of the invention can provide that the surface resistance of the base electrode layer is less than approximately 100 Ω/square.

An advantageous embodiment of the invention provides that the optical refraction index of the base electrode layer is less than approximately 1.5. Since light modes conducted in accordance with the above explanations should be avoided in the structural element, the formation of a base electrode with a refraction index of n<1.5 is preferably provided, because then in addition no total reflection of the incident light emitted in the organic layer range can take place on the boundary surface base electrode/glass substrate (typically n=1.5). Thus, at the most waveguiding modes still occur in the (glass) substrate that can, however, be prevented with traditional decoupling methods, for example, by roughened substrate bottom, decoupling foils or the like, so that even this light is also reflected, the optical refraction index of the base electrode layer is less than approximately 1.5.9

A further development of the invention preferably provides that the base electrode layer scatters light produced in the organic layer region and is formed for this purpose with a material porosity between approximately 1% and approximately 99%, preferably between approximately 20% and approximately 60%. Extent and quality of the material porosity can be influenced by selection of suitable process parameters during the formation of the base electrode. Thus, the selected coating process influences the packing density of the particles of electrically conductive oxide and therewith the porosity, for example, spin coating yields an approximately 10% higher degree of filling than inkjet printing. In particular, it is thus possible to produce a base electrode that has an excellent transparency for the light produced in the light-emitting range in spite of the desired layer density. The emission wavelength, that is slightly dependent on the angle of observation and that is normally expressed in a shift to shorter wavelengths, is also prevented by the produced porosity.

An advantageous embodiment of the invention can provide that the base electrode layer has a transmission capacity of at least 60% and preferably of at least 80% in the wavelength range of visible light.

A preferred embodiment of the invention provides that the organic layer range between the base electrode and the light-emitting range comprises at least one layer with a layer thickness of at least 100 nm, that transports charge carriers and is selectively electrically doped, with which a surface roughness of the base electrode layer is at least partially compensated.

An advantageous embodiment of the invention provides that the arrangement according to at least one construction type is selected from the following group of construction types: Transparent construction; construction emitting light through the cover electrode; construction emitting light through the base electrode; construction with a layer arrangement with a non-inverted structure in which the base electrode is an anode; and construction with a layer arrangement with an inverted structure in which the base electrode is a cathode.

A further development of the invention provides that the organic layer comprises one or more layers that are selectively multiply-formed, selected from the following group of layers: Electrically non-doped charge carrier transport layer, electrically doped charge carrier transport layer such as p-doped and n-doped charge carrier transport layer, block layer, electrically non-doped charge carrier injection layer and electrically doped charge carrier injection layer. The use of doped layers brings about an improved charge carrier injection into the organic range. This furthermore makes it possible that greater layer thicknesses can be used that for their part can compensate possible surface roughnesses of the base electrode. In the case of doped charge carrier transport layers the very good electrical conductivity is utilized. This avoids significant voltage drops via poorly electrically conductive layers, as is the case in the usage of non-doped materials. The electrical properties (IV characteristic curve) of the OLED are not adversely affected by the selection of greater layer thicknesses. However, if light interference effects are considered in the layer arrangement of the light-emitting component in the dimensioning of the layer thicknesses, layer thicknesses can be selected in this manner that bring about a reinforcement (constructive interference) in desired wavelength ranges of the light produced in the emission range and thus result in the increasing of the efficiency.

An advantageous embodiment of the invention can provide that the arrangement is formed on a carrier material selected from the following group of carrier materials: glass, flexible carrier material, metallic carrier material and plastic.

Preferred embodiment of the process for the production of the organic light-emitting component are explained in detail in the following.

A further development of the invention provides that the base electrode layer is printed on in a structured manner by a structuring process selected from the following group of structuring processes: Inkjet printing, offset printing, engraved printing, intaglio printing, thermotransfer printing, laser printing, flexo printing, silk screen printing and tampon printing. This makes it possible to apply the base electrode material exclusively in precisely the regions on the substrate that are comprised by a desired structure. Thus, only actually necessary amounts of the base electrode material are applied on the substrate. The controlling of the printing process for the base electrode material creates the possibility of adjusting a layout of the printed structures precisely in form and layer thickness. This eliminates maskings and/or lithography steps. Special manufactures with low peace numbers as well as individual copies can therefore be produced in a favorable manner without great additional technical expense. Furthermore, this achieves a simple scalability of the manufacture toward large substrate areas for one or more organic light-emitting components, for example, light-emitting diodes with printed-on base electrodes. In particular, a processing in vacuum systems as is customary in the state of the art is not necessary, so that substrates can be processed in any desired formats and forms for the application of the base electrode material.

A further development of the invention can provide that the base electrode layer is subsequently treated after the wet-chemical application from the dispersion of the base electrode material.

A preferred further development of the invention provides that the base electrode layer is sintered during the subsequent treatment at a temperature in a range between approximately 200° C. and approximately 1500° C., preferably between approximately 200° C. and approximately 800° C. and more preferably between approximately 300° C. and approximately 650° C. under gaseous atmosphere.

An advantageous further development of the invention provides that the gaseous atmosphere during the sintering comprises at least one gas selected from the following group of gasses: Ambient air, at least one protective gas such as argon, CO₂, nitrogen, noble gas and other non-reactive gas such as perhalogenated hydrocarbons.

An convenient embodiment of the invention can provide that the base electrode layer is formed during the subsequent treatment at a temperature in the range between approximately 20° C. and approximately 500° C. and preferably between approximately 150° C. and approximately 400° C. under a further gaseous atmosphere selectively formed equal to the gaseous atmosphere in the ratio of 99.9:0.1 to 0.1:99.9.

A further development of the invention can provide that the further gaseous atmosphere comprises during the forming at least one gas selected from the following group of gases: hydrogen and at least one protective gas such as argon, CO₂, nitrogen, noble gas.

The subsequent treatment by sintering or forming creates an intensive contact of the nanoparticles and therefore reduces the transitional resistance between the nanoparticles. This is achieved by a suitable process control, in which the original porosity and packing of the nanoparticles remains to the greatest possible extent and in that work is carried out only in the initial region of the sintering regime. Fissure formation in the layer and other disturbances were able to be avoided and at the same time the conductivity maximized by optimized heating and cooling times during the sintering and forming.

A further development of the invention preferably provides that the organic layer range is formed consisting exclusively of vapor-deposited, low molecular layers.

An advantageous further development of the invention provides that the cover electrode is formed by sputtering or thermal vaporization of a cover electrode material.

A further development of the invention preferably provides that the organic, light-emitting component is produced in a roller-to-roller process.

### DESCRIPTION OF PREFERRED EXEMPLARY EMBODIMENTS OF THE INVENTION

The invention is explained in detail in the following using exemplary embodiments with reference made to figures of the drawings.

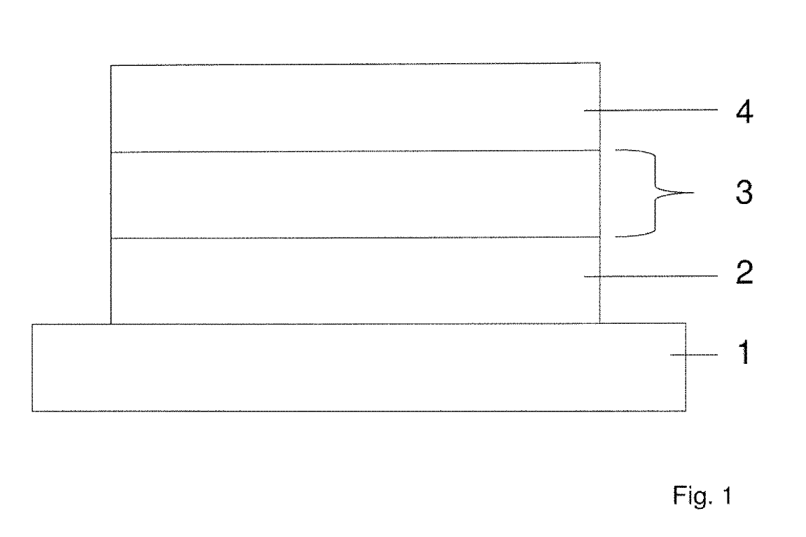

FIG. 1 shows a schematic view of an organic, light-emitting component with a layer arrangement with non-inverted construction in which a printed base electrode is designed as anode;

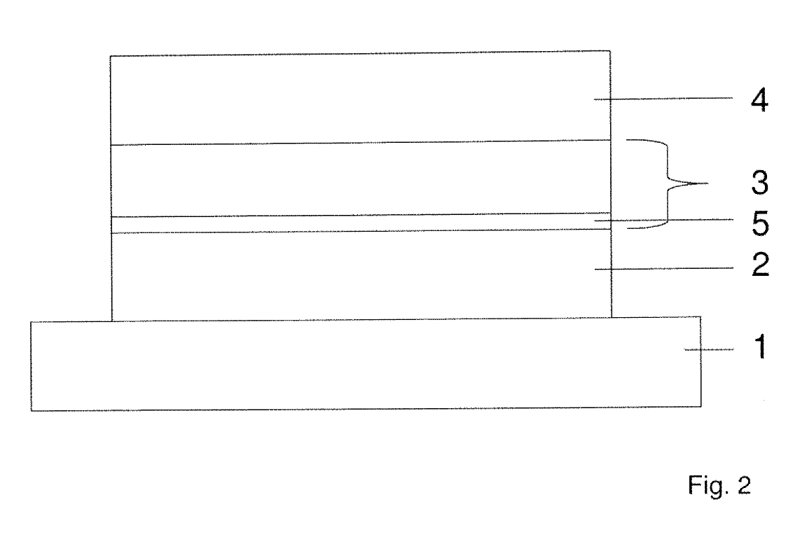

FIG. 2 shows a schematic view of an organic, light-emitting component with a layer arrangement with non-inverted construction in which the printed base electrode is designed as anode, in which an electrically doped charge carrier transport layer bordering on the base contact is provided;

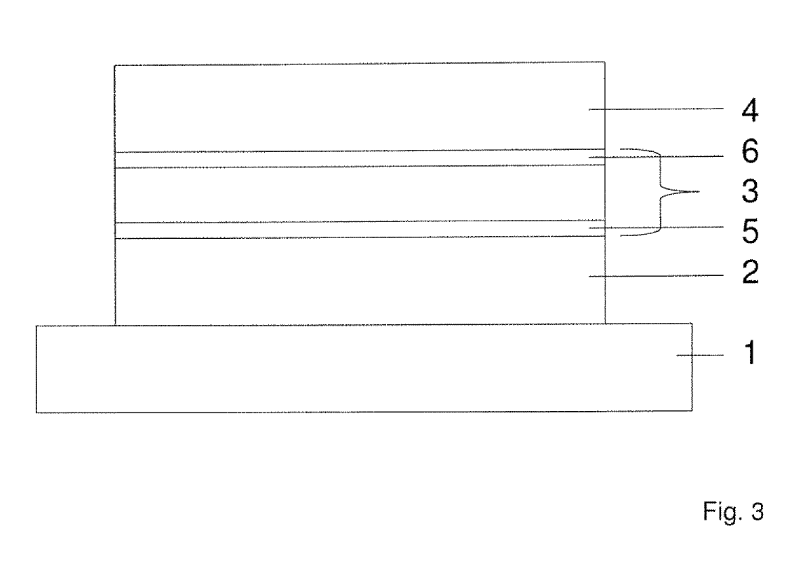

FIG. 3 shows a schematic view of an organic, light-emitting component with a layer arrangement with non-inverted construction in which the printed base electrode is designed as anode and electrically doped charge carrier transport layers are provided;

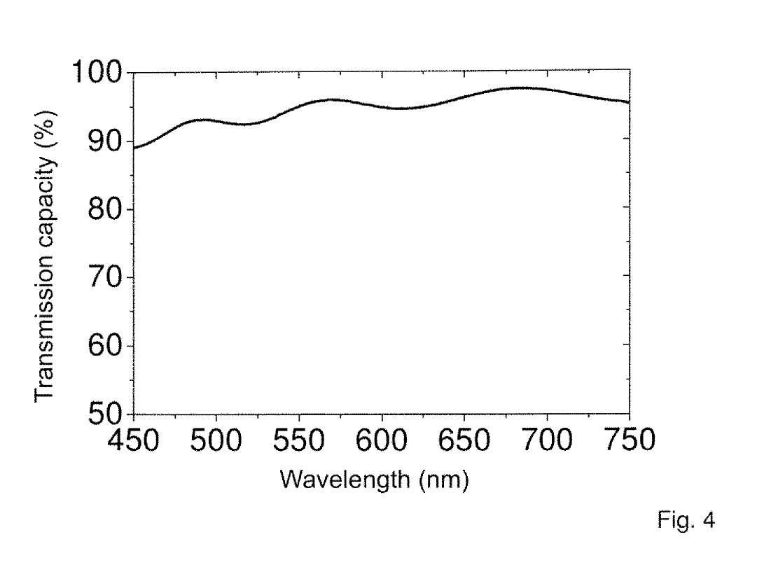

FIG. 4 shows a graphic view of the transmission capacity of a printed base contact from an ITO dispersion as a function of the wavelength;

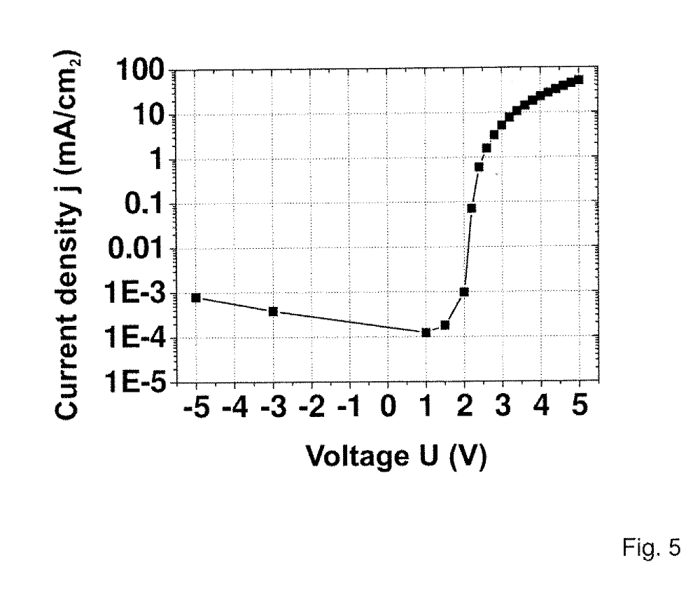

FIG. 5 shows a graphic view for a diode characteristic curve j(V) of an OLED with p- and n-doped charge carrier transport layers and a printed ITO base contact;

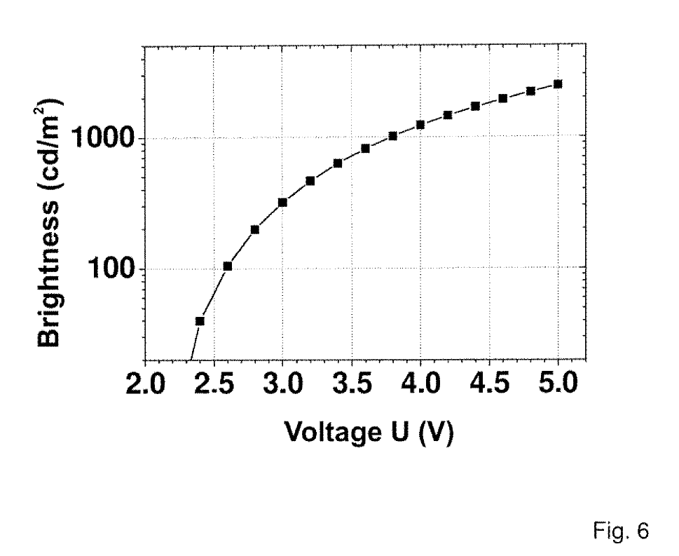

FIG. 6 shows a graphic view for a brightness curve L(V) of a red OLED with p and n-doped charge carrier transport layers and a printed ITO base contact;

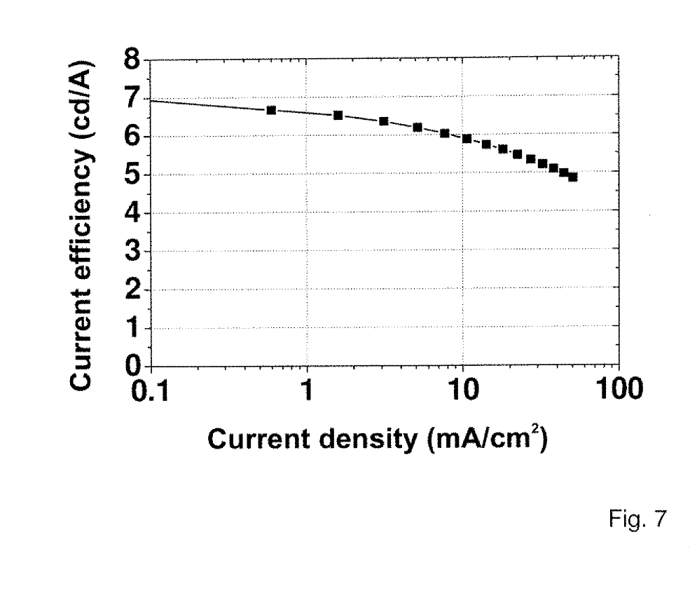

FIG. 7 shows a graphic view for the current efficiency of an OLED with p- and n-doped charge carrier transport layers and a printed ITO base contact;

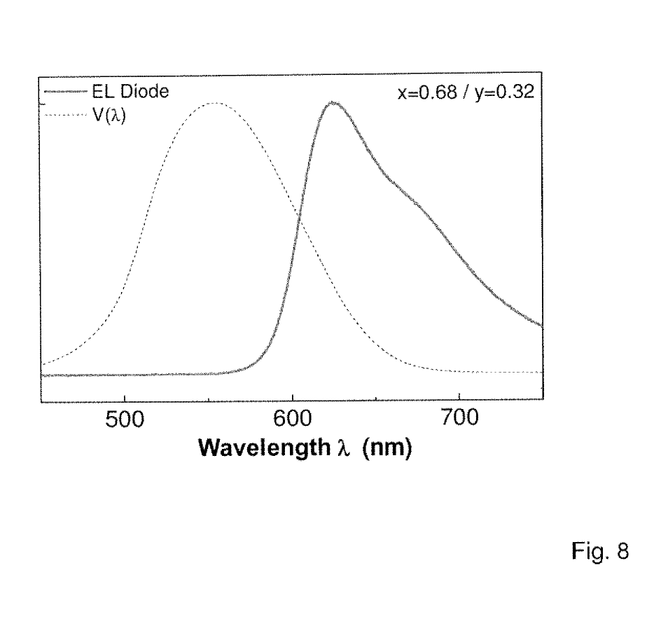

FIG. 8 shows a graphic view for the electroluminescence spectrum of a red OLED with p- and n-doped charge carrier transport layers and a printed ITO base contact;

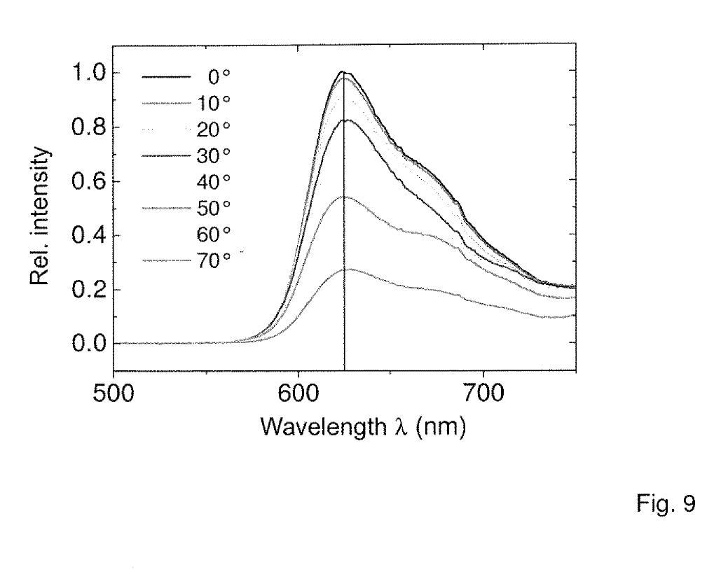

FIG. 9 shows a graphic view for electroluminescence spectra of a red OLED with p- and n-doped charge carrier transport layers and a printed ITO base contact as a function of the observation angle;

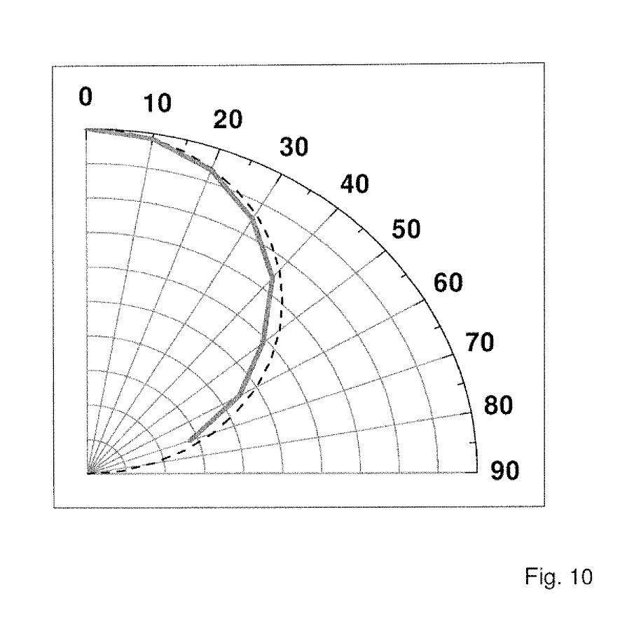

FIG. 10 shows a graphic view of the intensity of the radiated light of a red OLED with p- and n-doped charge carrier transport layers and a printed ITO base contact as a function of the observation angle (polar diagram);

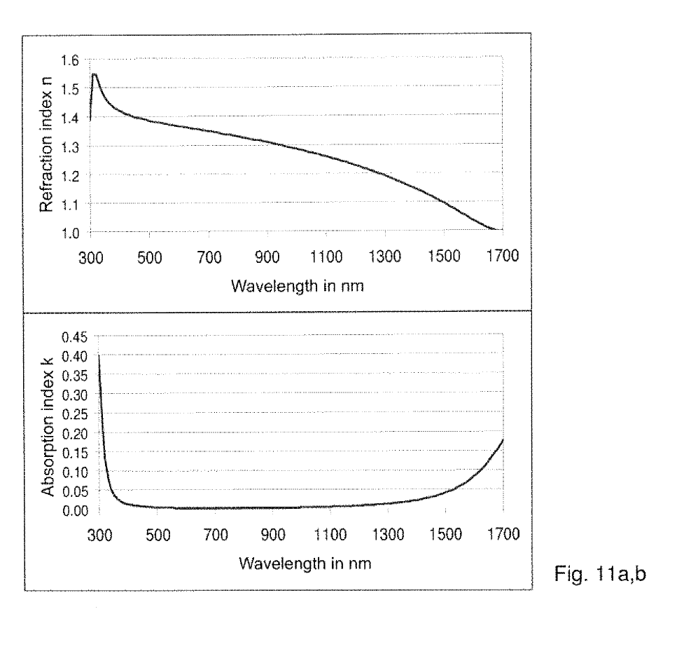

FIG. 11 shows a graphic view for the refraction index n and the absorption coefficient k of an ITO base electrode printed from a dispersion as a function of the wavelength, and

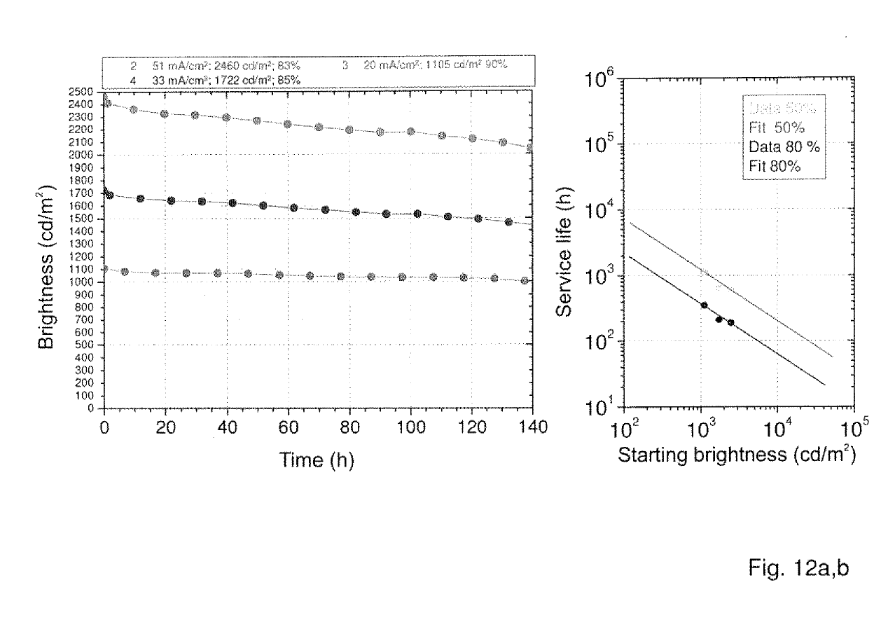

FIG. 12 shows a graphic view for a measuring of the service life of red OLEDs with p- and n-doped charge carrier transport layers and a printed ITO base contact at starting brightnesses of approximately 2460 cd/m², 1720 cd/m² and 1100 cd/m² with a double-logarithmic view for the extrapolation of service life up to 500 cd/m² is selected.

FIG. 1 shows a schematic view of an organic light-emitting component designed as organic light-emitting diode (OLED) with a layer arrangement with non-inverted construction.

A base electrode 2 of indium-tin oxide (ITO) is applied on a substrate 1. The base electrode 2 is followed by a stack 3 with organic layers. The closure is formed by a cover electrode 4, The substrate 1 serves as carrier material, which is glass in the exemplary embodiment shown. The base electrode 2 of ITO is formed as hole-injecting electrode (anode). It is constructed free of binding agent and transparent and has a layer thickness between approximately 0.05 μm and 20 μm, preferably between approximately 0.1 μm and 2 μm. The refraction index of the layer is less than 1.8. The surface roughness is between 2 nm and approximately 20 nm RMS, preferably less than approximately 10 nm RMS. The base electrode material ITO was printed on from a dispersion with the aid of a printing process.

The ITO base contact for organic light-emitting diodes is printed from a dispersion on the substrate. In tests the amount of the ITO, the wetting agents and the moisturizers were systematically varied in order to optimize the dispersion for the particular coating process. The viscosity and rheology, the zeta potential and the surface tension are decisive for the printing behavior.

At first, for example, aqueous or solvent-based dispersions of nanoparticles from electrically conductive oxides, for example ITO, are applied in a structuring coating process. Examples for structuring coating processes are in particular offset printing, intaglio-/engraved printing, thermotransfer printing, laser printing, flexo printing and Inkjet printing.

A sintering process then follows in accordance with the TCO used, namely, an electrically conductive oxide material with which optically transparent layers can be formed. This process can take place, for example, for ITO under atmosphere or protective gas such as, for example, nitrogen or argon at 400° C. to 600° C. for 30 min. to 5 h. Subsequently, a reduction of the surface oxygen content (forming) selectively takes place. The process takes place under pure hydrogen or a mixture of hydrogen and protective gas (for example, nitrogen or argon, hydrogen content 99.9%-0.1%) at a gas flow of statically up to 1000 l/h for 10 min to 4 h.

In this manner, for example, ITO layers with homogeneous thickness, high conductivity and high transmission capacity are obtained. The ITO contacts produced in this manner furthermore have a porosity of 20% to 60%, measured by X-ray fluorescence analysis (RFA). The above-described subsequent treatment by sintering and forming creates on the one hand an intensive contact of the nanoparticles and thus reduces the transition resistance between the nanoparticles. The measured surface resistance is reduced by several orders of magnitude. On the other hand, the original packing of the nanoparticles remains and their particulate character is retained to a very great extent. This is achieved by a suitable process control in which the original porosity and the packing of the nanoparticles remain to a very great extent and in that the work is performed only in the initial range of the sintering regime. Fissure formation in the layer and other disturbances were able to be avoided and at the same time the conductivity maximized by optimized heating and cooling times during the sintering and forming.

The following are especially useful as protective gas: Carbon dioxide, nitrogen, the group of the noble gases as well as non-reactive gases such as, for example, perhalogenated hydrocarbons.

In order to produce the composition used in the process, preferably electrically conductive nanoparticles selected from ternary systems such as, e.g., In₂O₃:Sn (ITO), SnO₂:Sb (ATO), SnO₂:F, ZnO:Al, ZnO:In, Zn—Sn—O, Mg—In—O, Ga—In—O, Zn—In—O, or quarternary systems such as, for example, Zn—In—Sn—O (ZITO), Zn—In—Li—O, or chemically and/or physically modified variants of these nanoparticles or a mixture of these nanoparticles and/or systems are used as TCO.

At least one organic, protic, aprotic, polar or nonpolar liquid or an inorganic liquid can be used in the process as dispersing agent for the composition. An acid, a glycol, a glycol ether, C1- to C8-carbohydrates, aromatic carbohydrates, aliphatic carbohydrates, aromatically or aliphatically halogenated hydrocarbons, S-, P- or Si-heterosubstituted hydrocarbons, or super-critical solvents, or silicones, or organic compounds, selected from mono-, oligo- or polymers, dyes, conductive organic compounds, non-oxidic inorganic compounds, metallo-organic compounds, organic compounds forming reactive intermediate stages, selected from benzoyl peroxide, azo-bis-isobutyronitrile, or a mixture of these organic compounds, or a mixture of these compounds can preferably be used in the process in accordance with the invention as dispersing agents, which dispersing agents can also be used in the particular super-critical pressure- and temperature range. A C1- to C12-alcohol, ester, or ether can be especially preferably used in the process in accordance with the invention as dispersing agent.

The stack 3 of organic layers comprises the following layers in the exemplary embodiment shown:
hole injection layer of CuPc (copper-phthalocyanine) or Starburst derivative with a layer thickness between approximately 5 nm and approximately 1000 nm, preferably between approximately 5 nm and 200 nm;
hole transport layer of TPD (tripheneldiamine) with a layer thickness between approximately 5 nm and approximately 1000 nm;
hole-side block layer for the preventing of an exiton diffusion from a light-emitting layer and for the preventing of a charge carrier leakage from the light-emitting layer of alpha-NPB (bis-naphtyl-phenylamino-biphenyl) with a thickness between approximately 2 nm and approximately 50 nm, preferably between approximately 5 nm and approximately 30 nm;
light-emitting layer of CBP (carbozol derivatives) with admixture of an emitter material in the form of phosphorescent triplet emitters such as iridium-tris-phenylpyridine Ir(ppy)₃ or Alq₃ (tris-quinolinato-aluminum) with a thickness between approximately 5 nm and approximately 100 nm, preferably between approximately 10 nm and approximately 30 nm;
electron-side block layer of BCP (bathocuproine) with a thickness between approximately 2 nm and approximately 50 nm, preferably between approximately 5 nm and approximately 30 nm;
electron transport layer of Alq₃ (tris-quinolinato-aluminum) with a thickness between approximately 10 nm and approximately 500 nm, preferably between approximately 20 nm and approximately 200 nm;
electron injection layer of inorganic lithium chloride (LiF) with a layer thickness between 0.5 nm and 5 nm.

The electron-injecting cover electrode 4 consists of a metal with a low work of separation, for example, aluminum. However, it can also be formed from electrically conductive oxides (TCOs, for example, ITO), metals such as Ba, Ca, Au, Ag, Cr, Mo, Ta, Ti, Ni, Pt, Zn, Zu, alloys/mixtures of the previous metals, metal oxides such as Ni_{y}Oₓ, Ti_{y}Oₓ, Pd_{y}Od, Pt_{y}Oₓ, Al_{y}Oₓ, Zn_{y}Oₓ, Ta_{y}Oₓ, MgO, Ca_{y}Oₓ, V_{y}Oₓ, Cu_{y}Oₓ, metal nitrides such as Ti_{y}Nₓ, Ni_{y}Nₓ, Pd_{y}Nₓ, Pt_{y}Nₓ, Ga_{y}Nₓ and with a thickness of at least approximately 10 nm.

FIG. 2 shows a schematic view of an organic light-emitting component in an embodiment as organic, light-emitting diode (OLED) with a layer arrangement with non-inverted construction in which the base electrode is an anode.

The substrate 1, the base electrode 2 as well as the cover electrode 4 are formed in accordance with the exemplary embodiment in FIG. 1. In addition, the organic, light-emitting component in FIG. 2 comprises a p-doped, hole-injecting and transporting layer 5 with a layer thickness between approximately 5 nm and approximately 1000 nm, preferably between approximately 40 nm and approximately 200 nm. An acceptor material F4-TCNQ is introduced as doping agent into a matrix material m-MTDATA for the electrical doping. The electrical doping of such charge carrier transport layers for the improving of the electrical conductivity for charge carriers to be transported by the transport layer is known as such.

The stack 3 of organic layers has the following construction in the exemplary embodiment according to FIG. 2:
hole-side block layer of alpha-NPB with a thickness between approximately 2 nm and approximately 50 nm, preferably between approximately 5 nm and approximately 30 nm;
light-emitting layer of TCTA with admixture of an emitter material in the form of Ir(ppy)₃ with a layer thickness between approximately 5 nm and approximately 100 nm, preferably between approximately 10 nm and approximately 30 nm;
electron-side block layer of BCP with a thickness between approximately 2 nm and approximately 50 nm, preferably between approximately 5 nm and approximately 30 nm;
electron transport layer of Alq₃ with a thickness between approximately 10 nm and approximately 500 nm, preferably between approximately 20 nm and approximately 200 nm;
electron injection layer of inorganic lithium chloride (LiF) with a layer thickness between 0.5 nm and 5 nm.

FIG. 3 shows a schematic view of an organic, light-emitting component designed as an organic, light-emitting diode (OLED) with a layer arrangement with non-inverted construction in which the base electrode is an anode. P- and n-doped charge carrier transport layers are provided that have a doping for the improvement of the electrical conductivity.

The substrate 1, the base electrode 2 of ITO, the stack 3 of organic layers, the cover electrode 4 as well as the p-doped injecting and transporting layer 5 are formed in accordance with the exemplary embodiment in FIG. 2.

In addition, an n-doped electron-injection and transporting layer 6 with a thickness between approximately 10 nm and approximately 500 nm, preferably between approximately 20 nm and approximately 200 nm is formed in the exemplary embodiment in FIG. 3. Cesium is embedded in a matrix material BPhen (Bathophenanthroline) as electrical doping material for improving the electrical conductivity. The doping of such a charge carrier transport layer for improving the electrical conductivity is known as such in various embodiments.

In distinction to the embodiments shown in the FIGS. 1 to 3, the organic, light-emitting structural part in the embodiment as organic, light-emitting diode (OLED) can also be formed with a layer arrangement with inverted construction, in which the base electrode is designed as cathode and the cover electrode as anode. In this case the electron-transporting layer borders on the printed ITO base electrode. Even in this embodiment doped charge carrier transport layers can be provided for the improvement of the performance parameters of the component.

If the base electrode 2 and the cover electrode 4 are constructed as transparent electrodes, this produces a transparent, organic, light-emitting structural part. Such a transparency is typically achieved by using thin metal layers, for example, of silver, gold, aluminum, magnesium, calcium or the like or a combination of them. Individual layers from multi-layered embodiments with transparent, conductive oxides can also be used, for example, ITO (indium-tin-oxide) or IZO (indium-zinc-oxide). Furthermore, anti-reflection coatings can be provided in order to improve the decoupling of light from the organic-light-emitting component.

Preferred embodiments are explained in detail in the following in conjunction with the stack 3 of organic layers.

The properties of organic materials in the stack 3 of organic layers can be described in detail by energetic levels, in particular referring to the lowest unoccupied molecular orbital (LUMO) and to the highest occupied molecular orbital (HOMO). Hole transport layers customarily have HOMOs in the range of 4.5 to 5.5 eV under vacuum level and LUMOs in the range of 1.5 to 3 eV. The organic materials for the light-emitting range customarily have HOMOs in the range of 5 to 6.5 eV and LUMOs in the range of 2 to 3 eV. The organic materials for electron transport layers customarily have HOMOs in the range of 5.5 to 6.8 eV and LUMOs in the range of 2.3 to 3.3 eV. The associated works of separation for the materials of the electrodes are in the range of 4 to 5 eV in the case of the anode and of 3 to 4.5 eV in the case of the cathode.

The materials that can be used for the n- or p-doping will now be explained in detail in the following.

The donor material (n-doping agent) is a molecule or a neutral radical with a HOMO level less than 3.3 eV, preferably less than 2.8 eV and more preferably less than 2.6 eV. The HOMO level of the donor can be determined from cyclovoltammetric measurements of the oxidation potential. The donor should have an oxidation potential that is less than or equal to approximately −1.5 V, preferably less or equal approximately −2.0 V, more preferably less than or equal to approximately −2-2 V in comparison to Fc/Fc+ (ferrocene/ferrocenium redox pair). The molar mass of the donor is between 100 and 2000 g/mol, preferably between 200 and 1000 g/mol. The molar doping concentration is between 1:1000 (acceptor molecule:matrix molecule) and 1:2, preferably between 1:100 and 1:5 and more preferably between 1:100 and 1:10.

The acceptor molecule (p-doping agent) is a molecule or a neutral radical with a LUMO level greater than 4.5 eV, preferably greater than 4.8 eV, more preferably greater than 5.04 eV. The LUMO level of the acceptor can be determined from cyclovoltammetric measurements of the reduction potential. The acceptor has a reduction potential that is greater than or equal to approximately −0.3 V, preferably greater than or equal to approximately 0.0 V and more preferably greater than or equal to approximately 0.24 V in comparison to Fc/Fc+. The molar mass of the acceptor is between 100 and 2000 g/mol, preferably between 200 and 1000 g/mol. The molar doping concentration is between 1:1000 (acceptor molecule:matrix molecule) and 1:2, preferably between 1:100 and 1:5 and more preferably between 1:100 and 1:10.

The layers of the stack 3 of organic layers are separated in a vacuum process by vapor deposition, for example, VTE (“Vacuum Thermal Evaporation”) or OVPD (“Organic Vapor Phase Deposition”). Furthermore, vacuum spray processes can be used. Another separation type comprises the thermally or optically induced transfer of the material from a carrier substrate onto the actual substrate, for example, LITI (“Laser Induced Thermal Imaging”).

The doped layers in the stack 3 of organic layers are produced in the vacuum by mixed evaporation from two independently regulated evaporation sources, namely, an evaporation source for the matrix material and an evaporation source for the doping material. Alternatively, they can also be produced by interdiffusion from a doping agent layer into the matrix material layer, during which the two materials are vapor-deposited sequentially in the vacuum. The interdiffusion can be thermally controlled.

Further embodiments for forming a base electrode from ITO of the organic, light-emitting structural element are described in detail in the following. A dispersion of ITO, that is then used to form the base electrode by inkjet printing, can be produced in various manners. In the following three exemplary embodiments for the production of the ITO dispersion are explained.

The ITO dispersion is produced in accordance with an embodiment using a “Dispermat CA” apparatus of the firm VMA-Getzmann GmbH. A dispersing container has a volume of one liter. YTZ bails based on yttrium with a diameter of 0.65 mm are used as grinding balls. The dispersing time is approximately two hours. If necessary, the temperature can be adjusted.

The following material combinations are preferred as educts:
a) 300 g AdNano® ITO (producer Degussa GmbH)
10 g 2-[2-(2-Methoxyethoxy)ethoxy]acidacid
290 g Ethanol:Isopropoxyethanol in the ratio 3:1
b) 200 g AdNano® ITO (producer Degussa GmbH)
25.3 g 2-[2-(2-Methoxyethoxy)ethoxy]acidacid
374.7 g Ethanol
50 g 1,2 Propandiol
c) 250 g AdNano® ITO (producer Degussa GmbH)
10 g 2-[2-(2-Methoxyethoxy)ethoxy]acidacid
216 g Ethanol
104 g 1,2 Propandiol
d) 250 g AdNano® ITO (producer Degussa GmbH)
10 g 2-[2-(2-Methoxyethoxy)ethoxy]acidacid
216 g Ethanol:Methyethylketone in the ratio 1:1
e) 125 g AdNano® ITO (producer Degussa GmbH)
375 g Water
18.75 g CT231 by Air-Products
f) 200 g AdNano® ITO (producer Degussa GmbH)
100 g Degalan P 26 Röhm
700 g Methylethylketone
g) 200 g AdNano® ITO (producer Degussa GmbH)
100 g Degalan P 26 Röhm
700 g Ethylacetate
h) 120 g AdNano® ITO (producer Degussa GmbH)
5 g Walocel MT 10000GO
875 g Water
i) 30 g AdNano® ITO (producer Degussa GmbH)
2.5 g Walocel MT 10000GO
67.5 g Isopropoxyethanol
j) 250 g AdNano® ITO (producer Degussa GmbH)
20 g Disperbyk 163
210 g Ethylacetate
k) 250 g AdNano® ITO (producer Degussa GmbH)
10 g Disperbyk 180
216 g Propanediol

At the beginning the ITO mixture is pre-dispersed ten minutes with an Ultaturax at 4000 rpm.

Before the filling in of the ITO dispersion the maximal and the minimal (approximately 2 cm above the minimal height) operating heights are to be adjusted. The YTZ balls (40 ml) are filled into a grinding basket. The opening of an immersion mill should be well covered since otherwise the optimal dispersing flow is not ensured. The rotational speed is now adjusted to 2200 rpm.

During the entire dispersing the mixture is cooled to 8 to 11° C. After two hours a sample is removed in order to determine the distribution of particle size with the aid of the type LB550 apparatus of the Horiba firm, The dispersing is ended when the D50 value is approximately 100 nm. Subsequently, the mixture is centrifuged for ten minutes at 4000 rpm. A filtration of the ITO dispersion then takes place by 0.5 μm Pal filter and the distribution of particle size is again determined with the Horiba apparatus. The following measured values were determined before and after the filtration:

| Before the filtration: | After the filtration: |
|---|---|
| D50: 100.9 nm | D50: 86.9 nm |
| D10: 69.4 nm | D10: 59.8 nm |
| D90: 135.9 nm | D90: 116.3 nm |

The viscosity is approximately 5 to 10 mPa. The dispersion has a homogenous, dark-blue coloring.

The ITO dispersion is produced in accordance with an alternative embodiment by the use of ultrasound, for example, using an ultrasonic finger (TYPE Dr. Hilscher UP 200S, microtip S7 sound output density 300 W/cm²). The above-cited material combinations are preferred as educts. The production of the dispersion takes place by ultrasonic dispersing with following evaluation of the particle size (approximately 0.1 to 0.2 μm) on the light microscope. The ultrasonic treatment time is 20 minutes.

The ITO dispersion is produced in accordance with a further embodiment by using a continuous flow cell. In this case, for example, the UIP 100 apparatus of Dr. Hilscher with sonotrode BS 34 is used (from surface diameter 34 mm, sound output density 95 W/cm²). Again, the above-cited material combinations are preferably used as educts.

The mixtures are mixed in the cited ratio in a beaker with a volume of 1:1 and then pumped through the continuous flow cell with a hose pump. The entire pumping time is 75 min at an amplitude of 100%, during which the dispersion is pumped in the circuit for the first 15 min. Thereafter, the mixture is pumped for an hour from one beaker into another beaker in order to ensure that all particles experienced an ultrasonic treatment at least once. After the ultrasonic treatment the distribution of particle size is measured with aid of the apparatus type LB550 of the Horiba firm. After 45 min the value is typically at D50-115 nm and after 75 min at D50=76 nm.

The produced dispersion of the ITO is then printed by a printer in a structured manner onto a cleaned glass substrate. For example, the printer PixDro LabP 150 of the Pixdro firm can be used here. The printing head used has the following parameters: Resolution—cross scan 838.45 dpi/in scan 846.67 dpi; quality factor 3; step size 32; mask file QF3 1×1; tension 60; GAP 1,00; T Chuk 26.8; air humidity 27% and direction of printing—first direction.

After the printing the layers formed are dried for one hour at 100° C. Subsequently, they are sintered one hour at 550° C. in a muffle furnace (C40) of the Nabertherm firm and thereafter formed two hours at 300° C. in a nitrogen-/hydrogen mixture 95:5 at a gas flow of 200 l/h. The surface resistances are after the sintering:
Field 1: 610 Ω/square, field 2: 602 Ω/square, field 3: 592 Ω/square, and after the forming:
Field 1: 58 Ω/square, field 2: 61 Ω/square, field 3: 63 Ω/square.

The base electrodes produced in this manner from ITO with a layer thickness of 0.6 to 2 μm typically have a roughness of 4 to 6 nm RMS. The transmission capacity is above 90% in the wavelength range of visible light (cf. FIG. 4) at a porosity of approximately 30 to 50%. The refraction index n=1.38 was determined by ellipsometer measuring (cf. FIG. 11).

An ITO base electrode was printed from dispersion by inkjet process on a cleaned glass substrate, sintered and subsequently formed.

Organic, light-emitting elements with red luminosity in the form of diodes with doped charge carrier transport layers were separated in a vacuum evaporation process without further treatment steps. In this case a 280 nm thick hole transport layer of spiro-TTB with a doping of 1.5 wt. % of the molecular p-doping agent F4-TCNQ (tetrafluorotetracyano-quinodimethane) was separated directly onto the ITO base electrode. This was followed by the buildup described above in a general manner with a hole-side intermediate layer NPD (10 nm), an emitter layer (20 nm) of NPD with admixed emitter ((tris(1-phenylisoquinoline)iridium (III), available, for example, from the firm American Dye Source) (20 w %>) and an electron-side intermediate layer BPhen (10 nm). The 50 nm thick electron transport layer consists of BPhen, into which cesium atoms are doped in with a ratio of 3:1. A layer of 150 nm vapor-deposited aluminum serves as reflecting cover electrode.

The elements were encapsulated with small cover glasses and a UV-hardening adhesive in order to characterize them electrooptically. The luminous surface is 6.7 mm².

The current-voltage characteristic curve of a structural element produced in this manner shows a clear diode behavior with reverse ratio of 70000 at 5 V and a small inverse current of <10⁻³ mA/cm² at −3 V (FIG. 5), which serves as demonstration that there are no short-circuits between the electrodes. Red light with color coordinates of 0.68/0.32 (FIG. 8) is radiated with a current efficiency of 5.5 cd/A (FIG. 7). A brightness of 1000 cd/m² is already achieved at a voltage of 3.75 V (FIG. 6). The color coordinates do not change under other observation angles (FIG. 9). The change in intensity corresponds to that of a typical Lambert emitter with cosine dependency (FIG. 10). The service life of this organic light-emitting structural element is 2000 h at 500 cd/m² (FIG. 12).

The features of the invention disclosed in the previous description, the claims and the drawings can be significant individually as well as in any combination for the realization of the invention in its different embodiments.

1. An organic light-emitting component, especially an organic light-emitting diode, in which an arrangement with a base electrode and a cover electrode as well as an organic layer region is formed that is arranged between the base electrode and the cover electrode and in electrical contact with the base electrode and the cover electrode, and which comprises at least one hole transport layer, at least one electron transport layer and one light-emitting region, in which:
the base electrode is formed by wet-chemical application from a dispersion as a structured, optically transparent base electrode layer free of binding agent from a base electrode material, namely, an optically transparent, electrically conductive oxide,
the base electrode layer has a surface resistance of less that approximately 500 Ω/square,
the base electrode layer has an optical refraction index of less than 1.8, and
a reverse blocking current less than approximately 10-2 mA/cm2 is in a current-voltage characteristic of the arrangement at a voltage of approximately −3V applied on the arrangement.

2. The component according to claim 1, characterized in that the base electrode material is formed by nanoparticles of electrically conductive materials.

3. The component according to claim 1, characterized in that the base electrode material is material of at least one material class selected from the following group of material classes: ternary material system such as In2O3:Sn (ITO), SnO₂:Sb (ATO), SnO2:F, ZnO:Al, ZnO:In, Zn—Sn—O, Mg—In—O, Ga—In—O, Zn—In—O; quarternary material systems such as Zn—In—Sn—O (ZITO), Zn—In—Li—O, chemically modified variant of the ternary material system, chemically modified variant of the quarternary material system, physically modified variants of the ternary material system, physically modified variants of the quarternary material system, and their mixtures.

4. The component according to claim 1, characterized in that the base electrode layer has a layer thickness between approximately 0.05 μm and approximately 20 μm, preferably between approximately 0.1 μm and approximately 2 μm.

5. The component according to claim 1, characterized in that the base electrode layer has an RMS roughness in the range of at least approximately 2 nm to at the most approximately 20 nm and preferably in the range of at the most approximately 10 nm.

6. The component according to claim 1, characterized in that the surface resistance of the base electrode layer is less than approximately 100 Ω/square.

7. The component according to claim 1, characterized in that the optical refraction index of the base electrode layer is less than approximately 1.5.

8. The component according to claim 1, characterized in that the base electrode layer scatters light and is formed with a material porosity between approximately 1% and approximately 99%, preferably between approximately 20% and approximately 60%.

9. The component according to claim 1, characterized in that the base electrode layer has a transmission capacity of at least 60% and preferably of at least 80% in the wavelength range of visible light.

10. The component according to claim 1, characterized in that the organic layer range between the base electrode and the light-emitting region comprises at least one layer with a layer thickness of at least 100 nm that transports charge carriers, with which a surface roughness of the base electrode layer is at least partially compensated.

11. The component according to claim 10, characterized in that the at least one layer transporting charge carriers is electrically doped.

12. The component according to claim 1, characterized in that the arrangement according to at least one construction type is selected from the following group of construction types: Transparent construction; construction emitting light through the cover electrode; construction emitting light through the base electrode; construction with a layer arrangement with a non-inverted structure in which the base electrode is an anode; and construction with a layer arrangement with an inverted structure in which the base electrode is a cathode.

13. The component according to claim 1, characterized in that the organic layer comprises one or more layers that are selectively multiply formed, selected from the following group of layers: Electrically non-doped charge carrier transport layer, electrically doped charge carrier transport layer such as p-doped and n-doped charge carrier transport layer, block layer, electrically non-doped charge carrier injection layer and electrically doped charge carrier injection layer.

14. The component according to claim 1, characterized in that that the arrangement is formed on a carrier material selected from the following group of carrier materials: glass, flexible carrier material, metallic carrier material, plastic.

15. A process for producing an organic light-emitting component, especially an organic light-emitting diode, in which an arrangement with a base electrode and a cover electrode as well as an organic layer region is formed that is arranged between the base electrode and the cover electrode and in electrical contact with the base electrode and the cover electrode, and which is formed with at least one hole transport layer, at least one electron transport layer and one light-emitting region, in which process the base electrode is formed wet-chemically from a dispersion of a base electrode material as a structured base electrode layer free of binding agent from a base electrode material, namely, an optically transparent, electrically conductive oxide, and in which the base electrode layer and the arrangement are configured in accordance with the following features: (i) A surface resistance of the base electrode layer is smaller than approximately 500 Ω/square, (ii) an optical refraction index of the base electrode layer is smaller than 1.8, and (iii) a inverse current is less than approximately 10-2 mA/cm2 in a current-voltage characteristic of the arrangement at a voltage of approximately −3 V applied on the arrangement.

16. The process according to claim 15, characterized in that that the base electrode layer is printed on in a structured manner by a structuring process selected from the following group of structuring processes: Inkjet printing, offset printing, engraved printing, intaglio printing, thermotransfer printing, laser printing, flexo printing, silk screen printing and tampon printing.

17. The process according to claim 15, characterized in that the base electrode layer is subsequently treated after the wet-chemical application from the dispersion of the base electrode material.

18. The process according to claim 17, characterized in that that the base electrode layer is sintered during the subsequent treatment at a temperature in a range between approximately 200° C. and approximately 1500° C., preferably between approximately 200° C. and approximately 800° C. and more preferably between approximately 300° C. and approximately 650° C. under gaseous atmosphere.

19. The process according to claim 18, characterized in that that the gaseous atmosphere during the sintering comprises at least one gas selected from the following group of gasses: Ambient air, at least one protective gas such as argon, CO2, nitrogen, noble gas and other non-reactive gas such as perhalogenated hydrocarbons.

20. The process according to one of the claim 17, characterized in that the base electrode layer is formed during the subsequent treatment at a temperature in the range between approximately 20° C. and approximately 500° C. and preferably between approximately 150° C. and approximately 400° C. under a further gaseous atmosphere selectively formed equal to the gaseous atmosphere in the ratio of 99.9:0.1 to 0.1:99.9.

21. The process according to claim 20, characterized in that the further gaseous atmosphere comprises during the forming at least one gas selected from the following group of gases: hydrogen and at least one protective gas such as argon, CO2, nitrogen, noble gas.

22. The process according to one of the claim 15, characterized in that the organic layer range is formed consisting exclusively of vapor-deposited, low molecular layers.

23. The process according to one of the claim 15, characterized in that the cover electrode is formed by sputtering or thermal vaporization of a cover electrode material.

24. The process according to one of the claim 15, characterized in the organic, light-emitting component is produced in a roller-to-roller process.

25. An article in a construction type selected from the following group of construction types: Illumination apparatus, display apparatus such as display or contact-sensitive surface, and characterizing device such as label or icon, characterized by at least one organic electronic component in accordance with claim 1.
